(19) United States
(12) Patent Application Publication
(10) Pub. No.: US 2012/0120611 A1
(43) Pub. Date: May 17, 2012

(54) SUPPORT COMPONENT STRUCTURE

(75) Inventors: Chung-Sheng Ni, Taipei (TW); Chun-Ying Yang, Taipei (TW)

(73) Assignee: INVENTEC CORPORATION, Taipei (TW)

(21) Appl. No.: 13/151,137

(22) Filed: Jun. 1, 2011

(30) Foreign Application Priority Data
Nov. 17, 2010 (TW) 099222301

(51) Int. Cl. H05K 7/16

(52) U.S. Cl. 361/727; 361/725

(57) ABSTRACT

A support component structure is removably installed on an electronic device, and is used to mount or dismount a printed circuit board in a frame of the electronic device. The support component structure includes a tray and at least one auxiliary support element. The tray is mounted on the frame in a combination manner, and is used to load the printed circuit board, so that the printed circuit board is mounted or dismounted in the frame. The auxiliary support element is mounted on the tray, and presses against the frame, so as to increase the weight that can be born by the tray.

### CROSS-REFERENCE TO RELATED APPLICATIONS

This non-provisional application claims priority under 35 U.S.C. §119(a) on Patent Application No. 099222301 filed in Taiwan, R.O.C. on Nov. 17, 2010, the entire contents of which are hereby incorporated by reference.

### BACKGROUND OF THE INVENTION

1. Field of Invention

The present invention relates to a support component structure, and more particularly to a support component structure erected on an electronic device, which is used to assist in mounting or dismounting of a printed circuit board in a frame.

2. Related Art

Nowadays, demand for computer equipment, such as desktop computers, notebook computers, and servers, is increasingly greater, and in order to obtain the latest and powerful function, consumer usually upgrades computer configurations.

In recent years, a network world is formed gradually, and people's life is inseparable from the network (such as internet surfing, online games, or the Bulletin Board System (BBS)). In order to build theses network platforms, servers with strong computing capability are required.

In order to save space, it is required to erect a server in limited space of a workroom, so that the bulk of a server case gets smaller and smaller to increase available space of the workroom. Since the bulk of the case gets smaller, and strong computing capability is required at the same time, the space of the case in which a printed circuit board is mounted is compressed. In order to make the computing capability of the server stronger, an operator is required to mount a plurality of mainboards in the case, and therefore the mounting and dismounting of the mainboards in the limited space becomes a time-consuming and laborious job.

In order to obtain a better audio-and-video effect and shorten a data transmission time, the operator usually needs to upgrade and maintain the mainboards, while the upgrade of the mainboards is bound to incur the job of the mounting and dismounting. Since it is not easy to employ a force due to small space, when the mainboards are mounted in the case, it is easy for the operator to accidentally drop the mainboards. Moreover, in order to enable the server to have the strong computing capability, a plurality of Central Process Units (CPUs) and display cards are mounted on the mainboards, so that each of mainboards is somewhat heavy, and the heaviness easily incurs occupational injuries to the operator in the long run. Since the price of each of the mainboards is not low, if the mainboard is accidentally dropped during the mounting and the dismounting, unnecessary station erection cost is incurred.

### SUMMARY OF THE INVENTION

Accordingly, the present invention is a support component structure, so that when a mainboard is mounted or dismounted, an operator is assisted by the support component structure, so as to solve a problem in which a printed circuit board is easy to be accidentally dropped during a mounting or dismounting process because when the printed circuit board is mounted or dismounted, the mounting and dismounting space around an electronic device is insufficient, and it is difficult for the operator to find a point to employ a force on.

The present invention provides a support component structure, which comprises a tray and at least one auxiliary support element. The tray is mounted on a frame of an electronic device in a combination manner, and is used to load a printed circuit board, so as to make it easy for the operator to push the printed circuit board into the frame, and to dismount the printed circuit board in the frame to take out. The auxiliary support element is mounted on the tray, and presses against the frame, so as to increase the weight of the goods able to be born by the tray.

According to the support component structure of the present invention, a pressing force direction of the auxiliary support element parallels a direction of the mounting and dismounting of the printed circuit board, so as to resist a force moment generated by the tray during the mounting or dismounting of the printed circuit board.

The effect of the support component structure of the present invention is as follows. The bearding board is added so as to provide a support platform, and thus the space of the mounting and dismounting is increased on one hand, and on the other hand the weight held by an operator is reduced when the operator puts the printed circuit board on the tray, so that the mounting and dismounting process becomes easier and the printed circuit board is not easily dropped on the ground.

In addition, the auxiliary support element pressing against the frame is added to increase the loading capacity of the tray, so that the tray is not out of shape due to overloading when the printed circuit board is put on the tray.

These and other aspects of the present invention will become apparent from the following description of the preferred embodiment taken in conjunction with the following drawings, although variations and modifications therein may be affected without departing from the spirit and scope of the novel concepts of the disclosure.

### BRIEF DESCRIPTION OF THE DRAWINGS

The accompanying drawings illustrate one or more embodiments of the invention and, together with the written description, serve to explain the principles of the invention. Wherever possible, the same reference numbers are used throughout the drawings to refer to the same or like elements of an embodiment, and wherein:

FIG. 1A is a schematic three-dimensional view of a support component structure according to a first embodiment of the present invention;

FIG. 1B is a schematic plane view of the support component structure according to the first embodiment of the present invention;

FIG. 2A is a schematic three-dimensional view of the support component structure according to a second embodiment of the present invention;

FIG. 2B is a schematic plane view of the support component structure according to the second embodiment of the present invention;

FIG. 3A is a schematic three-dimensional view illustrating that the support component structure according to a third embodiment of the present invention pushes a printed circuit board;

FIG. 3B is a schematic three-dimensional view illustrating that the support component structure according to the third embodiment of the present invention takes out the printed circuit board;

FIG. 4 is a schematic exploded view of a lateral plate of the support component structure according to the third embodiment of the present invention;

FIG. 5 is a schematic exploded view of a hook structure of the support component structure according to the third embodiment of the present invention;

FIG. 6 is a schematic exploded view of a joint portion of the support component structure according to the third embodiment of the present invention;

FIG. 7A is a schematic view of a pivot of the support component structure according to the third embodiment of the present invention; and

FIG. 7B is a schematic view of a pivot of the support component structure according to the third embodiment of the present invention.

### DETAILED DESCRIPTION OF THE INVENTION

The present invention provides a support component structure, which is removably mounted on a frame of an electronic device. The electronic device comprises an electronic device having a frame, such as a computer mainframe, or a server mainframe. The following takes the server mainframe as an example, but the present invention is not limited thereto.

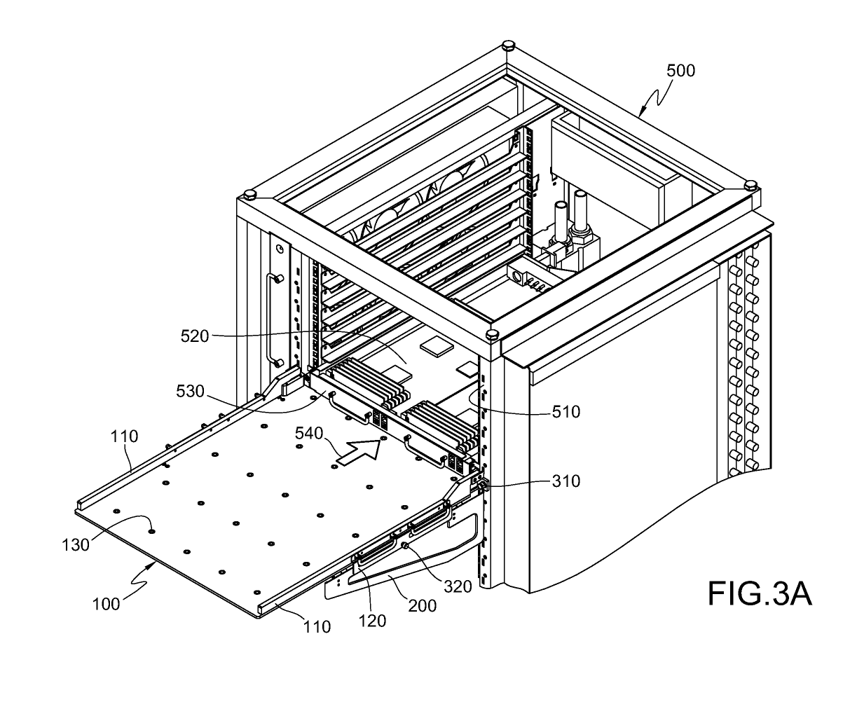

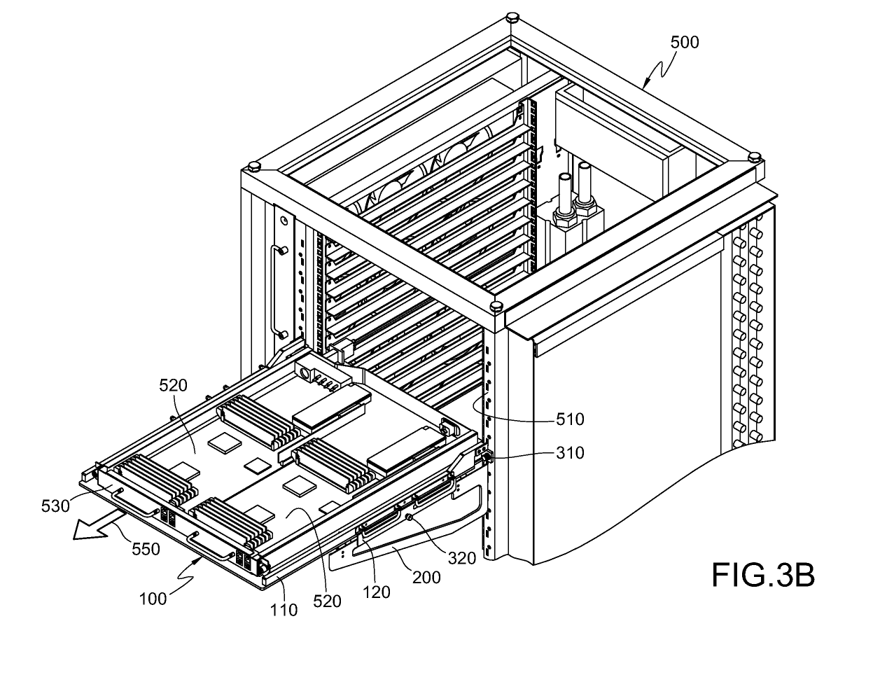

Referring to FIG. 3A and FIG. 3B, a printed circuit board 520 of the present invention is first put on a bearing plate 530, and then the printed circuit board 520 and the bearing plate 530 are put together on a tray 100, and then are pushed into a frame 510; during dismounting, the printed circuit board 520 and the bearing plate 530 are taken out simultaneously first, and then the printed circuit board 520 is removed from the bearing plate 530, but the present invention is not limited thereto.

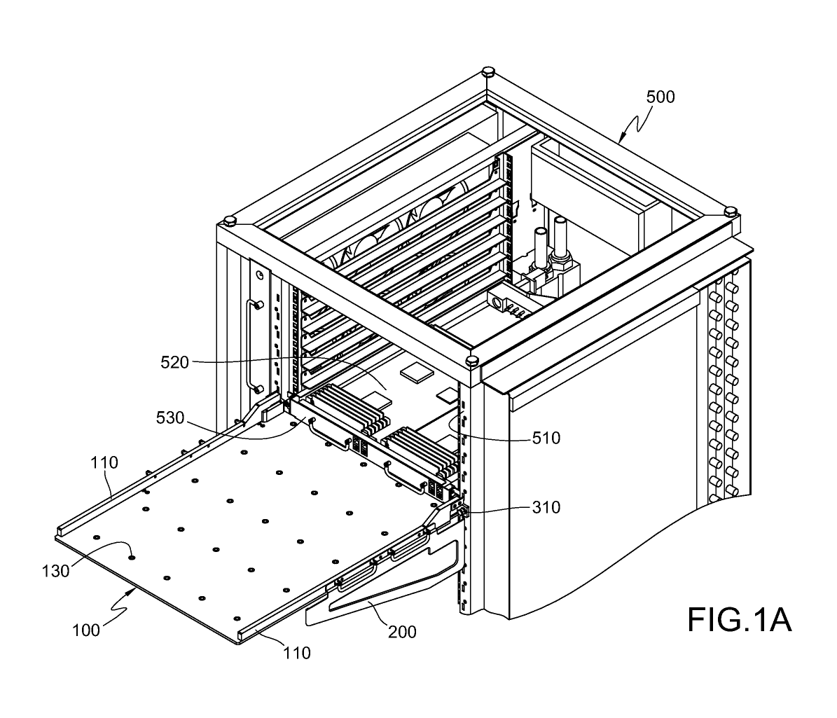

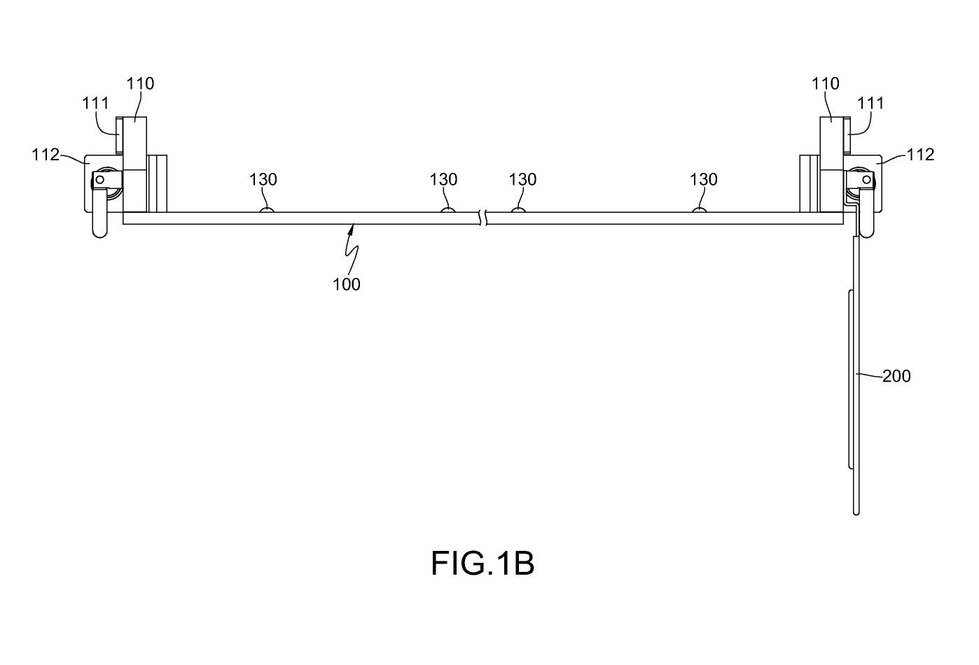

Referring to FIG. 1A and FIG. 1B, the support component structure according to a first embodiment of the present invention comprises a tray 100 and an auxiliary support element 200. When it is required to mount or dismount the printed circuit board 520, the tray 100 is first mounted on a frame 510 of an electronic device 500 in a combination manner, so that the printed circuit board 520 can be pushed into or taken out from the frame 510, and when the mounting or dismounting of the printed circuit board 520 ends, the tray 100 is dismounted from the frame 510.

The auxiliary support element 200 is disposed on any side of two opposite sides of the tray 100, so as to improve the bearing capacity of a single side of the tray 100.

In addition, the combination manner of the present invention refers to that the tray 100 is combined to the frame 510 through a clasp structure. When various printed circuit boards 520 are mounted, an erection location of the tray 100 is adjusted according to a location of the printed circuit board 520, and the clasp-structure combination manner facilitates the adjustment of the location of the tray 100 on the frame 510, thus reducing the mounting and dismounting time used by an operator, but the present invention is not limited thereto.

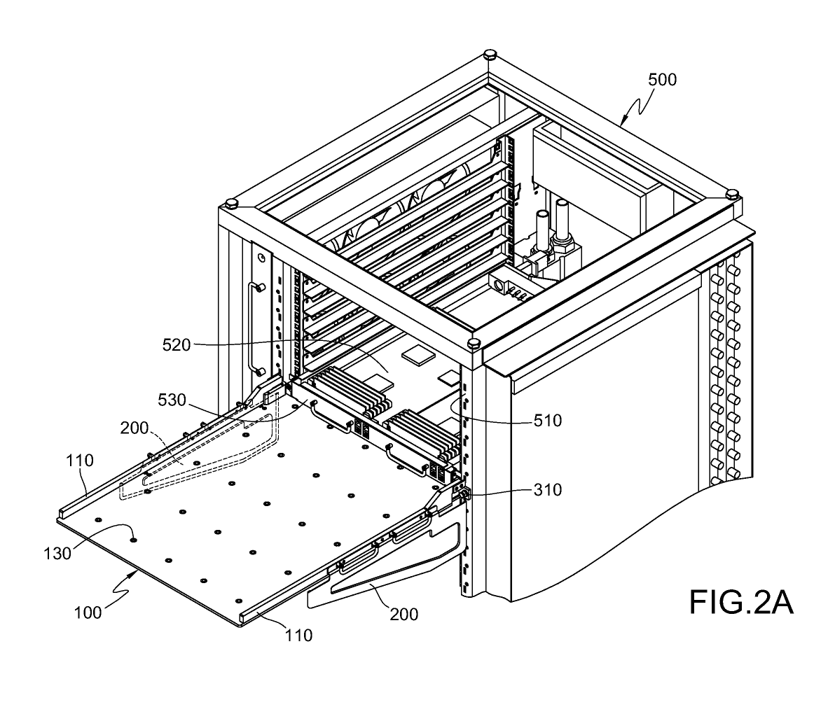

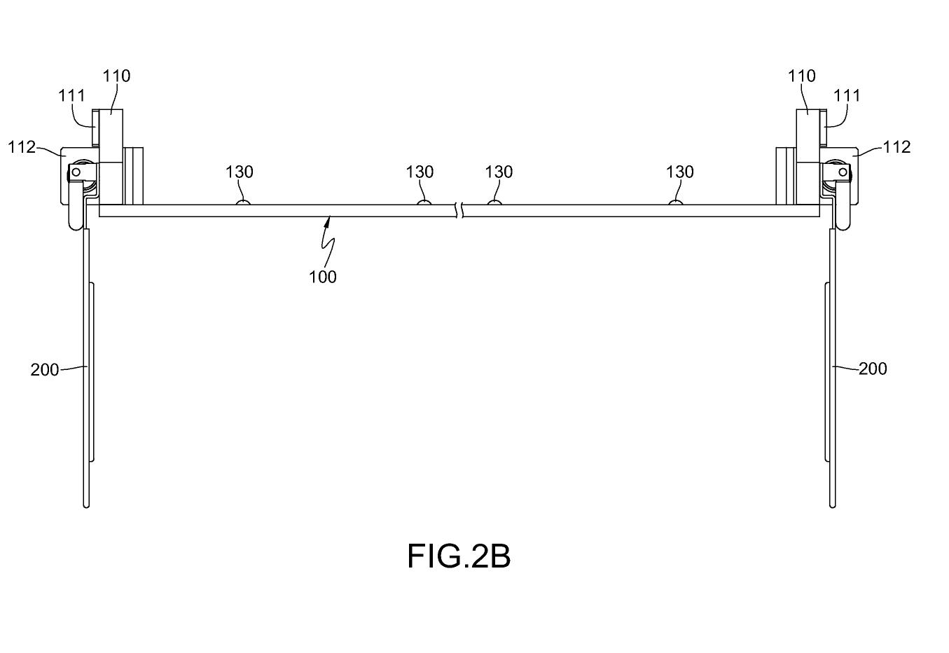

Referring to FIGS. 2A and 2B illustrating a support component structure according to a second embodiment of the present invention, and the support component structure of the second embodiment comprises a tray 100 and two auxiliary support elements 200. When it is required to mount or dismount a printed circuit board 520, a tray 100 is first mounted on a frame 510 of an electronic device 500 in a combination manner, so that the printed circuit board 520 can be pushed into or taken out from the frame 510, and when the mounting or dismounting of the printed circuit board 520 ends, the tray 100 is dismounted from the frame 510.

The two auxiliary support elements 200 are disposed in this embodiment, and are respectively disposed on the two opposite sides of the tray 100. Each of the auxiliary support elements 200 respectively presses against the frame 510, so that a pressing force is uniformly exerted on the two sides of the tray 100, thus keeping the placed tray 100 in balance and improving the bearing capacity of the two opposite sides of the tray 100 at the same time.

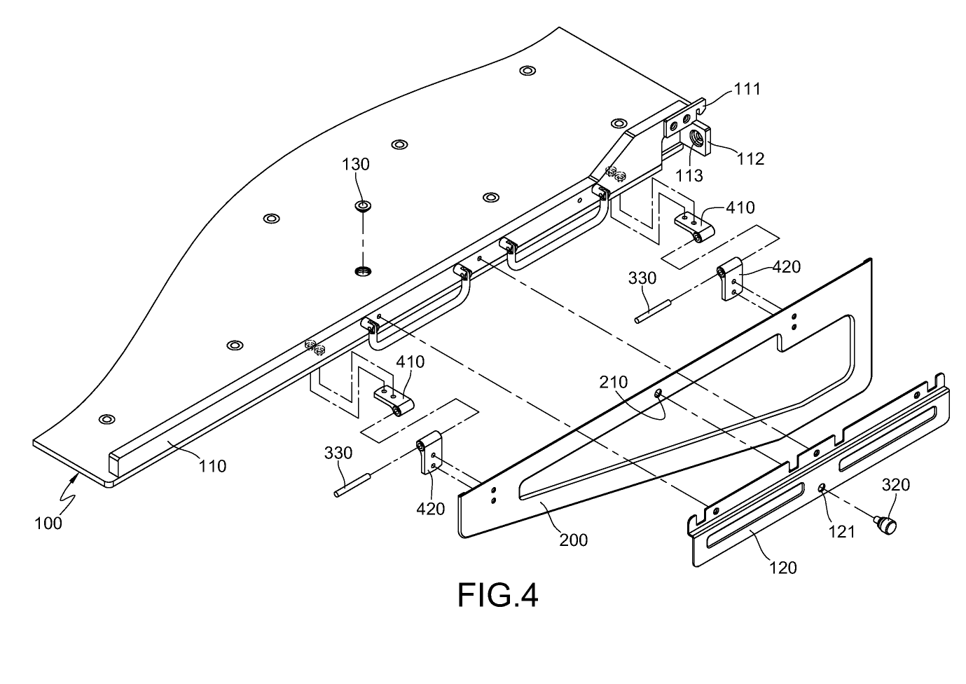

Referring to FIG. 3A to FIG. 4, a support component structure according to a third embodiment of the present invention comprises a tray 100 and at least one auxiliary support element 200. When it is required to mount or dismount a printed circuit board 520, a tray 100 is first mounted on a frame 510 of an electronic device 500 in a combination manner, so that the printed circuit board 520 can be pushed into or taken out from the frame 510, and when the mounting or dismounting of the printed circuit board 520 ends, the tray 100 is dismounted from the frame 510.

The auxiliary support element 200 is mounted on the tray 100, and presses against the frame 510. The pressing, by the auxiliary support 200, against the frame 510 generates a pressing force, so that the auxiliary support element 200 employs a support force on the tray 100, and thus an upper limit of the bearing the tray 100 is increased.

A rolling ball 130 is embedded in the tray 100, and a part thereof protrudes from a bearing surface of the tray 100. In addition, the rolling ball 130 may roll on and relative to the tray 100. Therefore, with the rolling feature of the rolling ball 130, the printed circuit board 520 is easier to glide on the tray 100 when the printed circuit board 520 is pushed in a pushing direction 540 or a taking-out direction 550, so as to push the printed circuit board 520 into the frame 510, or take out the printed circuit board 520 from the frame 510.

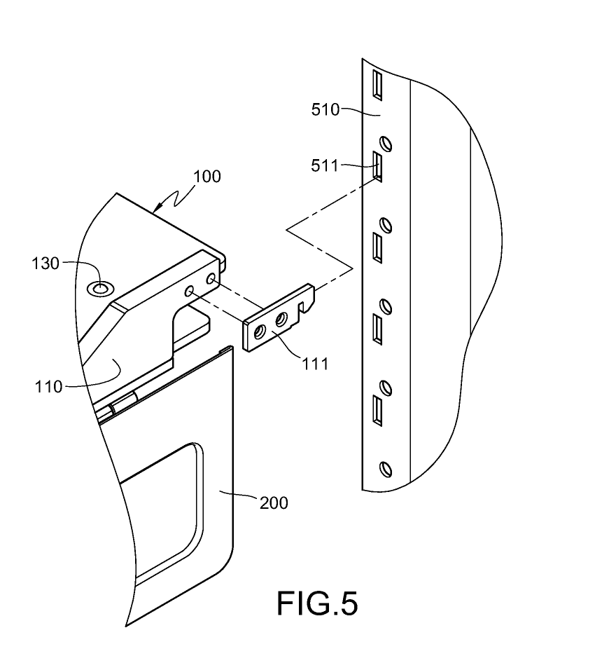

Referring to FIG. 4 and FIG. 5, the tray 100 further comprises two lateral plates 110 which are respectively disposed on two opposite sides of the tray 100. Each of the lateral plates 110 comprises a hook element 111, and the frame 510 has a plurality of hook holes 511 corresponding to the hook elements 111. During the mounting of the tray 100, the hook elements 111 are clasped in the hook holes 511, so that the tray 100 is inter-clasped with the frame 510 in such combination manner. During the dismounting of the tray 100, the hook elements 111 are removed from the hook holes 511, so that the tray 100 separates from the frame 510. Through the clasp structure of this embodiment, the mounting and dismounting of the support component structure of the present invention becomes faster and easier.

The support component structure is combined to the frame 510 in the clasp manner, but the present invention is not limited thereto. Replacement may be made by any person skilled in the art with other methods, such as a combination manner with a magnetic structure, or an electric-welding combination manner, and it is not limited to the embodiment of the present invention.

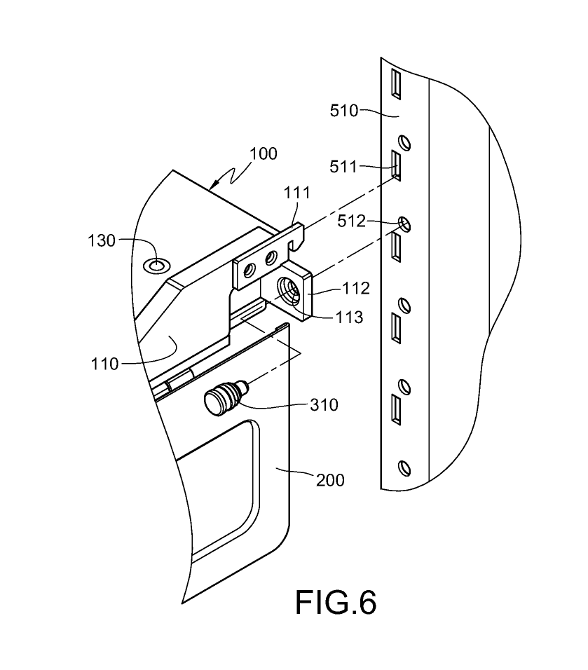

Referring to FIG. 4 and FIG. 6, a fixing element 112 may further be added, and mounted on each of the lateral plates 110 respectively, the fixing element 112 has a through hole 113, and the frame 510 has a gripping hole 512 corresponding to the fixing element 112. During the mounting of the tray 100, the hook element 111 is first clasped in the hook hole 511, and then a retaining element 310 (for example, a screw) may be inserted into the through hole 113 and combined to the gripping hole 512 when an object to be born is heavy, so that the tray 100 and the frame 510 are fixed to each other. During the dismounting of the tray 100, the dismounting is performed in a reverse order, so that the tray 100 separates from the frame 510.

The hook structure and the fixing structure exist simultaneously in the present invention. If the weight to be born by the tray 100 is relatively light, when the tray 100 is mounted on the frame 510, the hook structure is merely required perform clasping for combination, so as to improve efficiency and convenience of the mounting. If the weight to be born by the tray 100 is heavy, when the tray 100 is mounted on the frame 510, the hook structure and the fixing structure work at the same time to perform the combination, so that the tray 100 is fixedly combined to the frame 510.

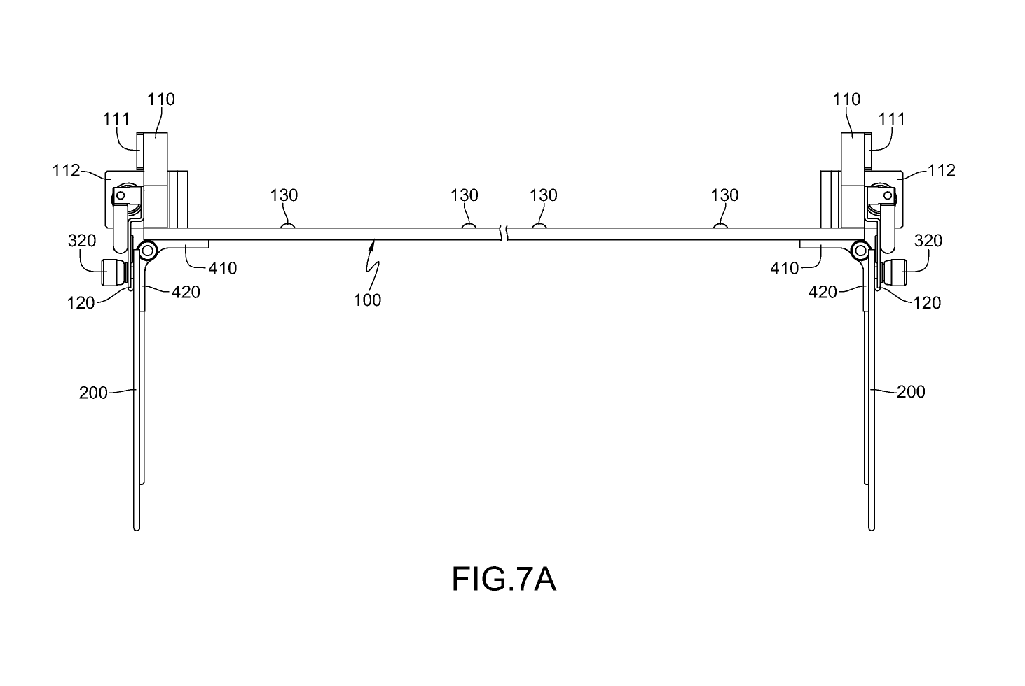

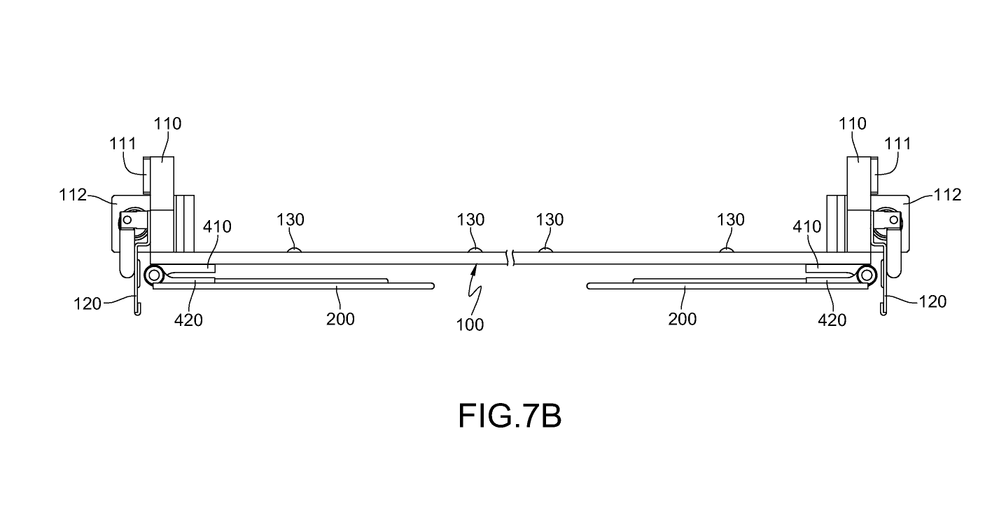

Referring to FIG. 3 to FIG. 7B, the two auxiliary support elements 200 are combined to the tray 100 through two sets of pivot elements respectively, so that the two auxiliary support elements 200 pivot between a first position and a second position, and selectively press against the frame 510.

Specifically, when the two auxiliary support elements 200 pivot to the first position, the two auxiliary support elements 200 press against the frame 510 at the same time, so as to provide the tray 100 with a support force. When the two auxiliary support elements 200 pivot to the second position, the two auxiliary support elements 200 simultaneously sway inward and separate from the frame 510, so as to facilitate the mounting and dismounting of the tray 100.

A set of the pivot element comprises a first pivot element 410, a second pivot element 420 and a shaft element 330 (for example, a bolt). The first pivot element 410 is fixedly disposed on the tray 100, the second pivot element 420 is fixedly disposed on the auxiliary support element 200, and the first pivot element 410 is combined to the second pivot element 420 through the shaft element 330 (for example, a bolt), so that the second pivot element 420 rotates relative to the first pivot element 410.

In this case, the tray 100 has a fixing board 120, which has a through hole 121, and the auxiliary support element 200 has a combination hole 210. When the tray 100 bears the printed circuit board 520, the auxiliary support element 200 is pivoted to the first position, so as to jointly support the printed circuit board 520 of the tray 100.

In order to prevent the auxiliary support element 200 from departing from the first position due to the sway of the tray 100, a penetration fixing element 320 (for example, a screw) is used to be inserted into the through hole 121 and is combined to the combination hole 210, so that the auxiliary support element 200 is fixed in the first position and does not deviate. When the tray 100 needs to be removed, the penetration fixing element 320 (for example, a screw) is loosened, so that the auxiliary support element 200 can pivot freely to return to the second position.

According to the support component structure of the present invention, the advantage lies in that a tray is added, and thus the space for mounting and dismounting the printed circuit board is increased on one hand, and on the other hand the weight held by the operator is reduced when the operator places the printed circuit board on the tray, so that the mounting and dismounting process becomes easier, and the printed circuit board is not easily dropped on the ground.

In addition, the two sets of the pivot elements are added to each of the auxiliary support elements, so that the auxiliary support element may pivot selectively, thus bringing convenience to the operation. When it is required to increase the support force, the auxiliary support element pivots to the first position, so that the tray is not out of shape due to the exceeding of the upper limit of the load. When the tray bears light load, the auxiliary support element is not required to pivot to the first position, so as to decrease the steps for mounting the tray. When the tray needs to be removed, the auxiliary support element pivots to the second position, so that the dismounting process is faster.

Additionally, the rolling ball is embedded in the tray, so as to reduce the friction between the printed circuit board and the tray when the printed circuit board glides on the tray, so that the mounting and dismounting of the printed circuit board demands less effort.

What is claimed is:

1. A support component structure, removably mounted on a frame of an electronic device and for mounting or dismounting a printed circuit board in the frame, and comprising:
a tray, mounted on the frame in a combination manner, and for loading the printed circuit board, so that the printed circuit board is mounted or dismounted in the frame; and
at least one auxiliary support element, mounted on the tray and pressing against the frame.

2. The support component structure according to claim 1, wherein the number of the at least one auxiliary support element is two, disposed on two opposite sides of the tray respectively and pressing against the frame respectively.

3. The support component structure according to claim 1, wherein the auxiliary support element is disposed on the tray in a pivot manner, so that the auxiliary support element pivots between a first position and a second position, wherein when the auxiliary support element is located in the first position, the auxiliary support element presses against the frame, and when the auxiliary support element is located in the second position, the auxiliary support element separates from the frame.

4. The support component structure according to claim 3, wherein the auxiliary support element further has at least one set of pivot elements comprising a first pivot element and a second pivot element, the first pivot element is fixedly disposed on the tray and the second pivot element is fixedly disposed on the auxiliary support element, and the first pivot element is combined to the second pivot element through an shaft element, so that the second pivot element rotates relative to the first pivot element.

5. The support component structure according to claim 3, wherein the tray has a fixing board, and when the auxiliary support element is located in the first position, the fixing board and the auxiliary support element are combined to each other.

6. The support component structure according to claim 5, wherein the auxiliary support element has a combination hole, the fixing board has a through hole, and a penetration fixing element is inserted into the through hole and is combined to the combination hole, so that the auxiliary support element is combined to the fixing board.

7. The support component structure according to claim 1, wherein the tray further has at least one lateral plate comprising a hook element, the frame has a hook hole corresponding to the hook element, and the hook element is clasped to the hook hole, so that the tray is combined to the frame.

8. The support component structure according to claim 7, wherein the lateral plate further comprises a fixing element having a through hole, the frame has a gripping hole corresponding to the fixing element, and a retaining element is inserted into the through hole and is combined to the gripping hole, so that the tray is combined to the frame.

9. The support component structure according to claim 1, wherein the tray has a plurality of rolling balls embedded in the tray and partly protruding from a bearing surface of the tray, and the rolling balls roll relative to the tray.
